(19) United States
(12) Patent Application Publication
(10) Pub. No.: US 2024/0088840 A1
(43) Pub. Date: Mar. 14, 2024

(54) Wireless Amplifier Circuitry

(71) Applicant: Apple Inc., Cupertino, CA (US)

(72) Inventors: Christian Tanzer, Perlesreut (DE); Julian Zuber, Erlangen (DE); Matthias Voelkel, Unterhaching (DE); Dominic Koehler, Viereth-Trunstadt (DE); Harald Pretl, Schwertberg (AT); Joonhoi Hur, Sunnyvale, CA (US); Rastislav Vazny, Saratoga, CA (US)

(21) Appl. No.: 18/359,458

(22) Filed: Jul. 26, 2023

Related U.S. Application Data
(60) Provisional application No. 63/406,123, filed on Sep. 13, 2022.

(51) Int. Cl. H03F 3/19

(52) U.S. Cl. CPC H03F 3/19; H03F 2200/294; H03F 2200/451

(57) ABSTRACT

An electronic device may include wireless circuitry with a processor, a transceiver circuit, a front-end module, and an antenna. The front-end module may include amplifier circuitry such as a low noise amplifier for amplifying received radio-frequency signals. The amplifier circuitry may operation in different modes based on its operating environment. Accordingly, the amplifier circuitry may include multiple amplifying cascode stages coupled in parallel, some of which may be selectively enabled. The amplifier circuitry may include an intermodulation distortion suppression circuit coupled to an amplifying cascode stage and an n-path filter coupled to another amplifying cascode stage. One or more of these amplifier circuitry portions may be active depending on its operating mode.

This application claims the benefit of U.S. provisional patent application No. 63/406,123, filed Sep. 13, 2022, which is hereby incorporated by reference herein in its entirety.

### FIELD

This application relates generally to electronic devices and, more particularly, to electronic devices with wireless communications circuitry.

### BACKGROUND

Electronic devices can be provided with wireless communications capabilities. An electronic device with wireless communications capabilities has wireless communications circuitry with one or more antennas. Wireless receiver circuitry in the wireless communications circuitry uses the antennas to receive radio-frequency signals.

Signals received by the antennas are fed through a radio-frequency front-end module, which can include a low noise amplifier for amplifying the received radio-frequency signals. It can be challenging to design satisfactory low noise amplifier circuitry for an electronic device.

### SUMMARY

An electronic device may include wireless circuitry with a processor, a transceiver circuit, a front-end module, and an antenna. The front-end module may include amplifier circuitry such as a low noise amplifier for amplifying received radio-frequency signals. The amplifier circuitry may include three amplifying cascode stages couples in parallel between the input port of the amplifier circuitry and the output port of the amplifier circuitry. The amplifier circuitry may include an intermodulation distortion suppression circuit coupled to the second amplifying cascode stage and an n-path filter coupled to the third amplifying cascode stage.

In particular, the first amplifying cascode stage may include a first amplification transistor coupled in series with a first cascode transistor, a source degeneration inductor, and input matching components. The second amplifying cascode stage may include a second amplification transistor coupled in series with a second cascode transistor, but lack at least some source degeneration components (e.g., have source degeneration components that differ from those coupled to the first amplification transistor in the first amplifying cascode stage) and lack at least some input matching components (e.g., have input matching components that different from those coupled to the first amplification transistor in the first amplifying cascode stage). The intermodulation distortion suppression circuit may include a transistor having a source terminal coupled between the second amplification transistor and the second cascode transistor. The transistor in the intermodulation distortion suppression circuit may be of a first transistor type (e.g., p-type transistor), while the second amplification transistor may be of a second transistor type (e.g., n-type transistor). The third amplifying cascode stage may include a third amplification transistor coupled in series with a third cascode transistor, a source degeneration inductor (e.g., have source degeneration components that are the same as those coupled to the first amplification transistor in the first amplifying cascode stage), and input matching components (e.g., have input matching components that are the same as those coupled to the first amplification transistor in the first amplifying cascode stage). The n-path filter may have a terminal coupled between the third amplification transistor and the third cascode transistor.

An aspect of the disclosure provides amplifier circuitry. The amplifier circuitry can include a first transistor having a gate terminal configured to receive a radio-frequency signal, a drain terminal coupled to an output port of the amplifier circuitry, and a source terminal. The amplifier circuitry can include a degeneration inductor coupled to the source terminal of the first transistor. The amplifier circuitry can include a second transistor having a gate terminal configured to receive the radio-frequency signal and a drain terminal. The amplifier circuitry can include a third transistor having a drain terminal coupled to the output port and a source terminal coupled to the drain terminal of the second transistor. The amplifier circuitry can include a fourth transistor having a source terminal coupled to the drain terminal of the second transistor.

An aspect of the disclosure provides amplifier circuitry. The amplifier circuitry can include a first transistor having a gate terminal configured to receive a radio-frequency signal, a drain terminal coupled to an output port of the amplifier circuitry, and a source terminal. The amplifier circuitry can include a degeneration inductor coupled to the source terminal of the first transistor. The amplifier circuitry can include a second transistor having a gate terminal configured to receive the radio-frequency signal and a drain terminal. The amplifier circuitry can include a third transistor having a drain terminal coupled to the output port and a source terminal coupled to the drain terminal of the second transistor. The amplifier circuitry can include an n-path filter coupled to the drain terminal of the second transistor.

An aspect of the disclosure provides an amplifier. The amplifier can include a first amplifying stage having a first terminal configured to receive a radio-frequency signal and a second terminal coupled to an output port of the amplifier. The amplifier can include a second amplifying stage having a first terminal configured to receive the radio-frequency signal and a second terminal coupled to the output port. The amplifier can include a noise suppression circuit coupled to the second amplifying stage. The amplifier can include a third amplifying stage having a first terminal configured to receive the radio-frequency signal and a second terminal coupled to the output port. The amplifier can include a filter circuit coupled to the third amplifying stage.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless communications circuitry having a front-end module in accordance with some embodiments.

FIG. 3 is a schematic diagram of an illustrative low noise amplifier in accordance with some embodiments.

FIG. 4 is a circuit diagram showing an illustrative implementation of a low noise amplifier of the type shown in FIG. 3 having an intermodulation distortion suppression circuit in accordance with some embodiments.

FIG. 5 is a circuit diagram showing an illustrative implementation of a low noise amplifier of the type shown in FIG. 3 having an additional amplifying stage and an n-path filter in accordance with some embodiments.

FIG. 6 is a diagram showing illustrative operating modes for a low noise amplifier of the type shown in FIGS. 3-5 in accordance with some embodiments.

### DETAILED DESCRIPTION

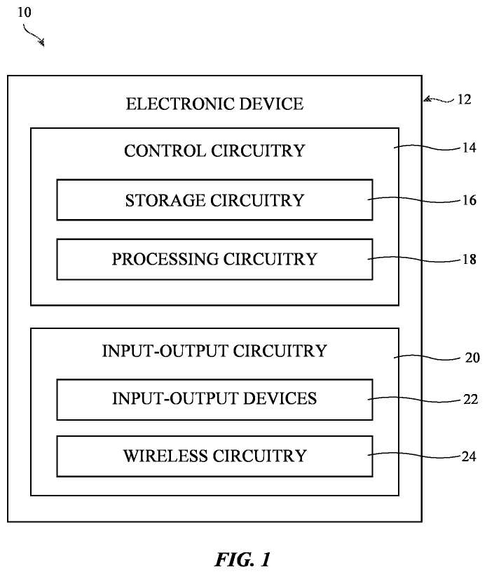

An electronic device such as electronic device 10 of FIG. 1 may be provided with wireless circuitry. The wireless circuitry may include an amplifier such as a low noise amplifier having multiple parallel amplifying stages, an intermodulation distortion suppression circuit, and a filter circuit. The multiple amplifying stages may each include a corresponding amplifying cascode. The intermodulation distortion suppression circuit may be coupled to one of the amplifying stages and may reduce intermodulation products generated within the low noise amplifier, thereby improving linearity of the low noise amplifier in at least one mode of operation. The filter circuit may include an n-path filter coupled to another one of the amplifying stages and configured to improve compression point of the low noise amplifier in at least one mode of operation.

By including the various above-mentioned circuits and amplifying stages, the low noise amplifier may be configured to meet or exceed one or more amplifier operating requirements (e.g., threshold levels) relating to gain, noise, linearity, compression point, power consumption, etc., even when operated in different modes of operation (e.g., for different radio access technologies, for different radio-frequency bands, in the presence of radio-frequency blockers, etc.). One or more low noise amplifiers containing these above-mentioned components can be included in any type of electronic device 10.

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include one or more microprocessors, microcontrollers, digital signal processors, host processors, baseband processor integrated circuits, application specific integrated circuits, central processing units (CPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols—sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 5G protocols, etc.), antenna diversity protocols, satellite navigation system protocols (e.g., global positioning system (GPS) protocols, global navigation satellite system (GLONASS) protocols, etc.), antenna-based spatial ranging protocols (e.g., radio detection and ranging (RADAR) protocols or other desired range detection protocols for signals conveyed at millimeter and centimeter wave frequencies), or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support wireless communications. Wireless circuitry 24 (sometimes referred to herein as wireless communications circuitry 24) may include one or more antennas. Wireless circuitry 24 may also include baseband processor circuitry or other processor circuitry, transceiver circuitry, amplifier circuitry, filter circuitry, switching circuitry, radio-frequency transmission lines, and/or any other circuitry for transmitting and/or receiving radio-frequency signals using the antenna(s).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), other centimeter or millimeter wave frequency bands between 10-300 GHz, near-field communications frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

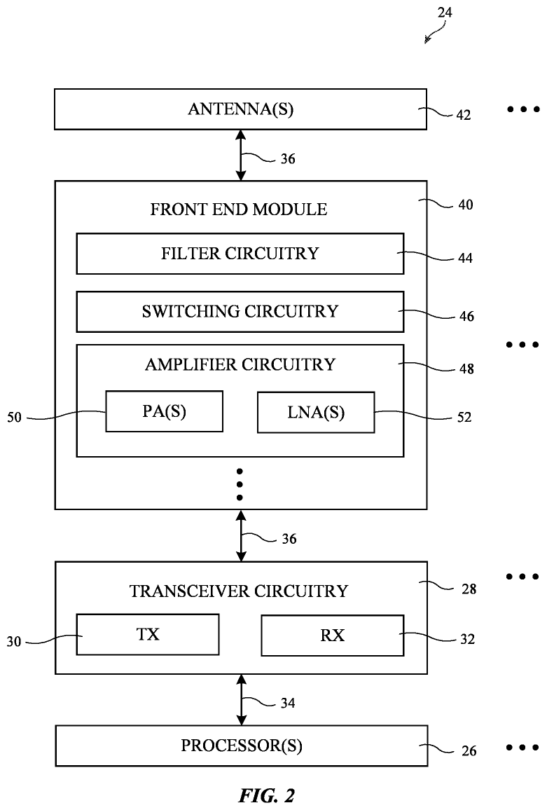

FIG. 2 is a diagram showing illustrative components within wireless circuitry 24. As shown in FIG. 2, wireless circuitry 24 may include one or more processors such as processor(s) 26, radio-frequency (RF) transceiver circuitry such as radio-frequency transceiver 28, radio-frequency front end circuitry such as radio-frequency front end module (FEM) 40, and antenna(s) 42. Processor 26 may be a baseband processor, an application processor, a digital signal processor, a microcontroller, a microprocessor, a central processing unit (CPU), a programmable device, a combination of these circuits, and/or one or more processors within circuitry 18. Processor 26 may be configured to generate digital (transmit or baseband) signals. Processor 26 may be coupled to transceiver 28 over path 34 (sometimes referred to as a baseband path). Transceiver 28 may be coupled to antenna 42 via radio-frequency transmission line path 36. Radio-frequency front end module 40 may be disposed on radio-frequency transmission line path 36 between transceiver 28 and antenna 42.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

In the example of FIG. 2, wireless circuitry 24 is illustrated as including only a single processor 26, a single transceiver 28, a single front end module 40, and a single antenna 42 for the sake of clarity. In general, wireless circuitry 24 may include any desired number of processors 26, any desired number of transceivers 36, any desired number of front end modules 40, and any desired number of antennas 42. Each processor 26 may be coupled to one or more transceiver 28 over respective paths 34. Each transceiver 28 may include a transmitter circuit 30 configured to output uplink signals to antenna 42, may include a receiver circuit 32 configured to receive downlink signals from antenna 42, and may be coupled to one or more antennas 42 over respective radio-frequency transmission line paths 36. Each radio-frequency transmission line path 36 may have a respective front end module 40 disposed thereon. If desired, two or more front end modules 40 may be disposed on the same radio-frequency transmission line path 36. If desired, one or more of the radio-frequency transmission line paths 36 in wireless circuitry 24 may be implemented without any front end module disposed thereon.

Front end module (FEM) 40 may include radio-frequency front end circuitry that operates on the radio-frequency signals conveyed (transmitted and/or received) over radio-frequency transmission line path 36. FEM 40 may, for example, include front end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifier circuits 50 and/or one or more low-noise amplifier circuits 52), impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front end module components may be mounted to a common (shared) substrate such as a rigid printed circuit board substrate or flexible printed circuit substrate. If desired, the various front end module components may also be integrated into a single integrated circuit chip.

Filter circuitry 44, switching circuitry 46, amplifier circuitry 48, and other circuitry may be disposed on radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards. In one suitable arrangement, radio-frequency transmission line paths such as radio-frequency transmission line path 36 may also include transmission line conductors integrated within multilayer laminated structures (e.g., layers of a conductive material such as copper and a dielectric material such as a resin that are laminated together without intervening adhesive). The multilayer laminated structures may, if desired, be folded or bent in multiple dimensions (e.g., two or three dimensions) and may maintain a bent or folded shape after bending (e.g., the multilayer laminated structures may be folded into a particular three-dimensional shape to route around other device components and may be rigid enough to hold its shape after folding without being held in place by stiffeners or other structures). All of the multiple layers of the laminated structures may be batch laminated together (e.g., in a single pressing process) without adhesive (e.g., as opposed to performing multiple pressing processes to laminate multiple layers together with adhesive).

Transceiver circuitry 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

As described above, front end module 40 may include one or more low noise amplifiers (LNAs) 52 in the receive (downlink) path. It may be desirable for a low noise amplifier 52 (sometimes referred to as low noise amplifier circuitry or amplifier circuitry) to amplify a received radio-frequency signal without significantly degrading the signal-to-noise (SNR) ratio of the amplified signal. Low noise amplifier 52 may, for example, be used to provide 2 dB of voltage gain, 3 dB of voltage gain, 4 dB of voltage gain, 5 dB of voltage gain, 6 dB of voltage gain, 3-4 dB of voltage gain, 2-5 dB of voltage gain, 5-10 dB of voltage gain, or other suitable amounts of voltage gain.

Additionally, it may be desirable for amplifier circuitry 52 to amplify an input radio-frequency signal having one or more desired radio-frequencies in a linear manner such that the output signal is proportional to the input signal, e.g., at least across the voltages and frequencies of operation. In particular, in the presence of one or more radio-frequency blockers, high linearity of amplifier circuitry 52 may enable subsequent removal of these undesired signal components (e.g., at blocker frequencies). Furthermore, for some radio access technologies, it may be desirable for amplifier circuitry 52 to exhibit a high compression point (e.g., a point above which the linear gain (transfer) characteristic of the amplifier is distorted by an undesired amount), thereby extending the linear operating regime of amplifier circuitry 52.

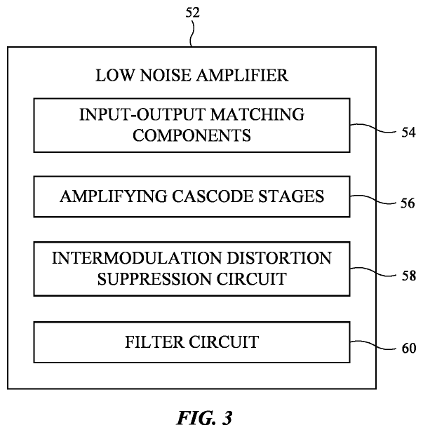

A low noise amplifier such as amplifier circuitry 52 may include one or more components configured to address one or more of these considerations (e.g., relating to gain, noise, linearity, compression point, etc.). FIG. 3 is a schematic diagram of an illustrative low noise amplifier 52. As shown in FIG. 3, low noise amplifier 52 may include input and/or output matching components 54 such as those for an input matching network and/or output matching network, one or more amplifying stages such as amplifying cascode stages 56, non-linearity suppression circuitry such as an intermodulation distortion suppression circuit 58, and filter circuitry such as filter circuit 60.

An input port of low noise amplifier 52 configured to receive an input radio-frequency signal to be amplified may be coupled to input matching components 54 forming an input matching network. The input matching network may be configured to provide a proper input impedance at the input port of low noise amplifier 52 to help provide maximal power transfer while minimizing signal reflection back to the preceding stage in front end module 40. In an analogous manner, output matching components 54 forming an output matching network may help provide maximal power transfer to downstream circuitry.

One or more amplifying stages 56 in amplifier 52 may form the core amplification circuit. Each of amplifying stages 56 may include an amplification transistor that provide the main amplification transfer function for that stage of low noise amplifier 52. As an example, in a simple configuration, an amplifying stage may include one main amplification transistor that receives the input radio-frequency signal at its gate terminal and generates an amplified output signal at its drain terminal.

In some illustrative arrangements described herein as an example, amplifying stages 56 may each include a cascode amplifier (sometimes referred to herein as an amplifying cascode) formed by coupling a cascode transistor in series with the above-mentioned amplification transistor. In these arrangements, stages 56 may be referred to herein as amplifying cascode stages 56.

To provide enhanced amplification characteristics (e.g., high gain, low noise, low power consumption, etc.), one or more stages 56 may be coupled in parallel. In other words, the one or more stages 56 may each include an amplification transistor coupled to the same input port of amplifier 52 and coupled to the same output port of amplifier 52 (via the corresponding cascode transistor).

If desired, one or more additional amplifying stages may be coupled in series with stages 56 (e.g., the output of one amplifying stage may be coupled to the input of a succeeding stage) to provide sequential amplification functions.

In some arrangements, one or more stages 56 may include other components that enhance the performance of the amplification transistor(s), of the amplifying cascode(s), and/or of low noise amplifier 52. As an example, one or more stages 56 may include degeneration inductor circuitry (e.g., degeneration transformer circuitry) having one or more inductors coupled to the respective source terminal(s) of one or more amplification transistors. Providing inductive components at the source terminals within low noise amplifier 52 (a technique sometimes referred to as source degeneration) may affect the gain and the input impedance of the coupled amplification transistor. In particular, increasing the overall inductance of the degeneration inductor circuitry may reduce the voltage gain of the amplification transistor. Accordingly, decreasing the overall inductance of the degeneration inductor circuitry may increase the voltage gain of the amplification transistor. The inductance of the degeneration inductor may also affect a quality factor (Q factor) associated with the input impedance of the amplification transistor. In particular, decreasing the overall inductance of degeneration inductor circuitry may increase the Q factor of the input impedance. Accordingly, increasing the overall inductance of the degeneration inductor circuitry may reduce the Q factor of the input impedance. In such a manner, the performance of the amplification transistor and amplifier 52 may be enhanced by providing and tuning the parameters of the degeneration inductor circuitry.

In some arrangements, components such as the amplification transistor(s) within one or more amplifying stages 56 may produce or otherwise exhibit non-linear behavior (e.g., inherently or caused by other coupled components and/or input radio-frequency signals). To suppresses this type of non-linear behavior, low noise amplifier 52 may include non-linearity suppression circuitry such as intermodulation distortion suppression circuit 58.

As an example of non-linear behavior, an amplification transistor may exhibit a negative third-order non-linearity coefficient gm3 (sometimes referred to as the third-order transconductance). In the absence of any suppression scheme, this non-zero non-linearity coefficient gm3 may lead the amplification transistor to exhibit intermodulation distortion when receiving certain types of input radio-frequency signals (e.g., those that contain blocker frequency signals), thereby causing the amplification transistor to produce an output signal with an undesirable third-order intermodulation. To suppress the generation of this undesired intermodulation component and/or other intermodulation distortion effects, low noise amplifier 52 may include intermodulation distortion suppression circuit 58. This example is illustrative of only some of the non-linear behavior that can be exhibited within low noise amplifier 52. Low noise amplifier 52 may exhibit other types of non-linear behavior suppressed by intermodulation distortion suppression circuit 58.

In some arrangements, amplifier 52 may further improve its linearity (e.g., by improving amplifier compression point and thereby extending the linear operating regime). As an example, amplifier 52 may include a filter circuit such as filter circuit 60 configured to increases the compression point of amplifier 52. In arrangements described herein as an example, filter circuit 60 may be an n-path filter.

The various constituent components described in connection with input-output matching components 54, amplifying stages 56, intermodulation distortion suppression circuit 58, and filter circuit 60 as part of amplifier 52 shown in FIG. 3 are illustrative. If desired, any of these components might optionally be excluded from low noise amplifier 52. If desired, low noise amplifier 52 may also include other components necessary to enable proper amplification without introducing excessive noise.

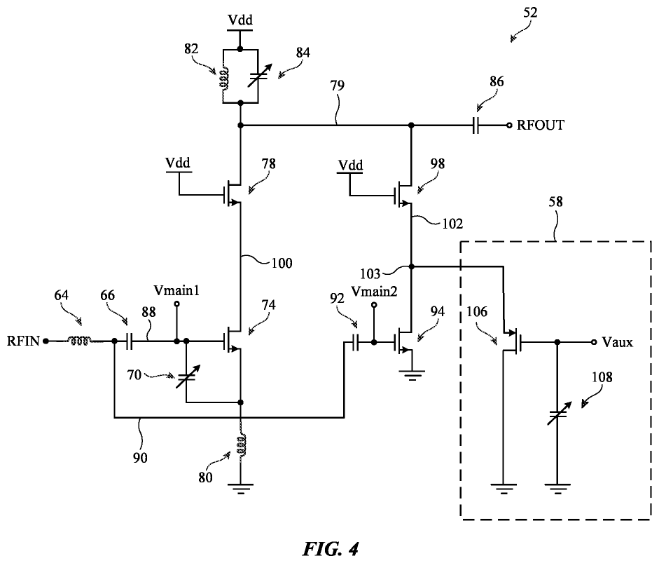

FIG. 4 is a circuit diagram illustrating one configuration of low noise amplifier 52. As shown in FIG. 4, low noise amplifier 52 may include an input port (terminal) RFIN configured to receive a radio-frequency input signal from an antenna. As described in connection with FIG. 2, one or more circuits such as filter circuitry, switching circuitry, antenna tuning circuitry, and/or other control circuitry may optionally be coupled along the radio-frequency transmission line path between the antenna and the amplifier input port RFIN. A local input matching network may be coupled to input terminal RFIN.

In the example of FIG. 4, the local input matching network may include a series inductor such as inductor 64 with a first terminal coupled to the RFIN port and a second terminal coupled to a series capacitor such as capacitor 66. Capacitor 66 may have a first terminal coupled to inductor 64 and a second terminal coupled to amplification transistor 74. Input matching network 54 may include a shunt capacitor such as variable capacitor 70 (having a tunable capacitance) and shunt inductor such as inductor 80. Capacitor 70 may have a first terminal coupled to the second terminal of capacitor 66 and a second terminal coupled to inductor 80. Inductor 80 may have a first terminal coupled to capacitor 70 and a second terminal coupled to a ground power supply line (sometimes referred to as ground line on which ground voltage Vss is provided).

This example in which the input matching network includes inductors 64 and 80 and includes capacitors 66 and 70 is illustrative. As other examples, input matching network 54 might include two or more of passive components (e.g., capacitors, inductors, and/or resistors) coupled in some series and/or shunt configurations relative to one another. In general, input matching network 54 may include any suitable number of passive components connected in a hybrid series-shunt configuration. If desired, the hybrid series-shunt configuration of the passive components may form frequency-selective filters such as notch filters for filtering out one or more frequencies based on the input signal received at input RFIN.

Amplification transistor 74 (sometimes referred to as core amplification transistor 74 or main amplification transistor 74) may be coupled to input port RFIN via input path 88 (along which inductor 64 and capacitor 66 are coupled). Transistor 74 may be an n-type transistor (e.g., an n-channel transistor such as an n-type metal-oxide-semiconductor or NMOS device). N-type transistor 74 may have a drain terminal coupled to path 100, a gate terminal coupled to input RFIN, and a source terminal coupled to inductor 80. The terms “source” and “drain” are sometimes used interchangeably when referring to a transistor. The source and drain terminals are therefore sometimes referred to as source-drain terminals (e.g., a transistor has a gate terminal and first and second source-drain terminals).

Inductor 80 may serve as source degeneration inductor circuitry. Inductor 80 may couple the source terminal of transistor 74 (at a first terminal of inductor 80) to a ground power supply line (at a second terminal of inductor 80).

The gate terminal of transistor 74 may be configured to receive a bias voltage Vmain1 (e.g., through a bias voltage line coupled to the gate terminal of transistor 74 and supplying the bias voltage). Voltage Vmain1 may have some intermediate voltage level between the ground voltage level and a positive power supply voltage level Vdd that powers amplifier 52.

The drain terminal of transistor 74 may be coupled to a cascode transistor such as transistor 78. Transistor 78 in combination with amplification transistor 74 may sometimes be referred to as a cascode amplifier, a cascode amplifier circuit, an amplifying cascode stage, or simply an amplifying cascode. Amplification transistor 74 and cascode transistor 78 may collectively form one of the multiple amplifying stages 56 (FIG. 3) in amplifier 52.

Cascode transistor 78 may be an n-type transistor having a gate terminal coupled to a positive power supply line supplying voltage level Vdd, a source terminal coupled to amplification transistor 74, and a drain terminal coupled to a radio-frequency output port RFOUT of amplifier 52 via output path 79. In particular, the output terminal of this cascode amplifier stage (e.g., at the drain terminal of transistor 78) may produce the output radio-frequency signal corresponding to an amplified version of the input radio-frequency signal received at input RFIN.

In the example of FIG. 4, output matching components such as inductor 82 and variable capacitor 84 may be coupled in parallel between output path 79 and a positive power supply line supplying voltage level Vdd. Output path 79 may be coupled to output port RFOUT via an output capacitor such as capacitor 86. The output port RFOUT of amplifier 52 may be coupled to a downstream stage such as a mixer stage in transceiver circuitry 28 for down-converting or demodulating signals. If desired, the output(s) of amplifier 52 may be passed to other stages in front end module 40 and/or transceiver circuitry 28 before being received by processor 26.

As shown in FIG. 4, amplifier 52 may further include a second amplifying stage in additional to the first amplifying stage formed from amplification transistor 74 and cascode transistor 78. In particular, inductor 64 and a series capacitor such as capacitor 92 may couple the input port RFIN to the second amplifying stage. Amplification transistor 94 (sometimes referred to as core amplification transistor 94 or main amplification transistor 94) may be coupled to input port RFIN via input path 90 (along which inductor 64 and capacitor 92 are coupled). Transistor 94 may be an n-type transistor. N-type transistor 94 may have a drain terminal coupled to path 102, a gate terminal coupled to input RFIN, and a source terminal coupled to a ground power supply line.

The gate terminal of transistor 94 may be configured to receive a bias voltage Vmain2 (e.g., through a bias voltage line coupled to the gate terminal of transistor 94 and supplying the bias voltage). Voltage Vmain2 may have some intermediate voltage level between the ground voltage level and a positive power supply voltage level Vdd that powers amplifier 52. Voltage Vmain2 provided to transistor 94 may be the same or different from voltage Vmain1 provided to transistor 74.

The drain terminal of transistor 94 may be coupled to a cascode transistor such as transistor 98. Transistor 98 in combination with amplification transistor 94 may sometimes be referred to as a cascode amplifier, a cascode amplifier circuit, an amplifying cascode stage, or simply an amplifying cascode. Amplification transistor 94 and cascode transistor 98 may collectively form (another) one of the multiple amplifying stages 56 (FIG. 3) in amplifier 52.

Cascode transistor 98 may be an n-type transistor having a gate terminal coupled to a positive power supply line supplying voltage level Vdd, a source terminal coupled to amplification transistor 94, and a drain terminal coupled to the radio-frequency output port RFOUT via output path 79. In particular, the output terminal of this cascode amplifier stage (e.g., at the drain terminal of transistor 98) may produce the output radio-frequency signal corresponding to an amplified version of the input radio-frequency signal received at input RFIN.

Configured in the above-described manner, the first and second amplifying stages may perform amplification operations for an input radio-frequency signal received at input port RFIN in parallel, thereby both contributing to the output radio-frequency signal at output port RFOUT.

To suppress (e.g., cancel) undesired intermodulation products generated by the first and second amplifying stages (e.g., by amplification transistors 74 and 94), amplifier 52 may include an intermodulation distortion suppression circuit. As shown in FIG. 4, intermodulation distortion suppression circuit 58 may be coupled to terminal 103 between amplification transistor 94 and cascode transistor 98.

In particular, intermodulation distortion suppression circuit 58 may include transistor 106 coupling terminal 103 to a ground power supply voltage line supplying ground voltage Vss. In particular, transistor 106 may be a p-type transistor (e.g., a p-channel transistor such as a p-type metal-oxide-semiconductor or PMOS device). P-type transistor 106 may have a source terminal coupled to terminal 103, a gate terminal coupled to a bias voltage line supplying bias voltage Vaux, and a drain terminal coupled to the ground power supply voltage line. Voltage Vaux provided to transistor 106 may be the same or different from voltage Vmain1 provided to transistor 74 and/or may be the same or different from voltage Vmain2 provided to transistor 94.

While transistor 106 is illustrated as a p-type transistor and other transistors in low noise amplifier 52 are illustrated as an n-type transistor, if desired, the types of these transistors may be interchanged (e.g., along with other components and power supply voltages, and their interconnections within amplifier 52).

Intermodulation distortion suppression circuit 58 may include a capacitor such as variable capacitor 108 coupled between the gate terminal of transistor 106 and a ground power supply voltage line. Capacitor 108 and voltage Vaux may be used to tune the intermodulation distortion properties of circuit 58.

In the example of FIG. 4, the first amplifying stage (e.g., transistor 74) may contribute to most of the gain behavior and may contribute significantly to undesired (third-order) intermodulation components in the output radio-frequency signals. The second amplifying stage (e.g., transistor 94) may contribute to a portion of the undesired (third-order) intermodulation components that is shifted in phase (e.g., due to a lack of source degeneration for transistor 94). Transistor 106 in intermodulation distortion suppression circuit 58 may contribute to a cancellation component that is opposite in phase (e.g., 180 degrees phase-shifted) to the intermodulation components generated by the second amplifying stage. In particular, p-type transistor 106 may exhibit intermodulation components that are opposite in sign with respect to intermodulation components generated by n-type transistors 94 and 74, thereby resulting in the components generated by transistor 106 being a cancellation component in reference to the intermodulation components generated by transistors 94 and 74.

In other words, the cancellation component generated by transistor 106 may reduce (e.g., cancel out) the undesired intermodulation components generated by the second amplifying stage and/or reduce the undesired intermodulation components generated by the first amplifying stage. By providing a degeneration inductor such as inductor 80 or other source degeneration circuitry for the first amplifying stage, while omitting a degeneration inductor or other source degeneration circuitry for the second amplifying stage, the intermodulation components generated by the second amplifying stage may exhibit a phase shift with respect to the intermodulation components generated by the first amplifying stage. The addition of this phase shift and the coupling of transistor 106 to the second amplifying stage improves the cancelation of intermodulation components within amplifier 52. Additionally, bias voltages Vaux, Vmain1, and Vmain2 may be supplied independently to transistors 106, 74, and 94, respectively. As such, this intermodulation distortion suppression scheme (e.g., adjustable based on multiple independently controlled bias voltages, a tunable phase shift between first and second amplifying stages, etc.) may desirably provide numerous degrees of freedom for intermodulation distortion suppression.

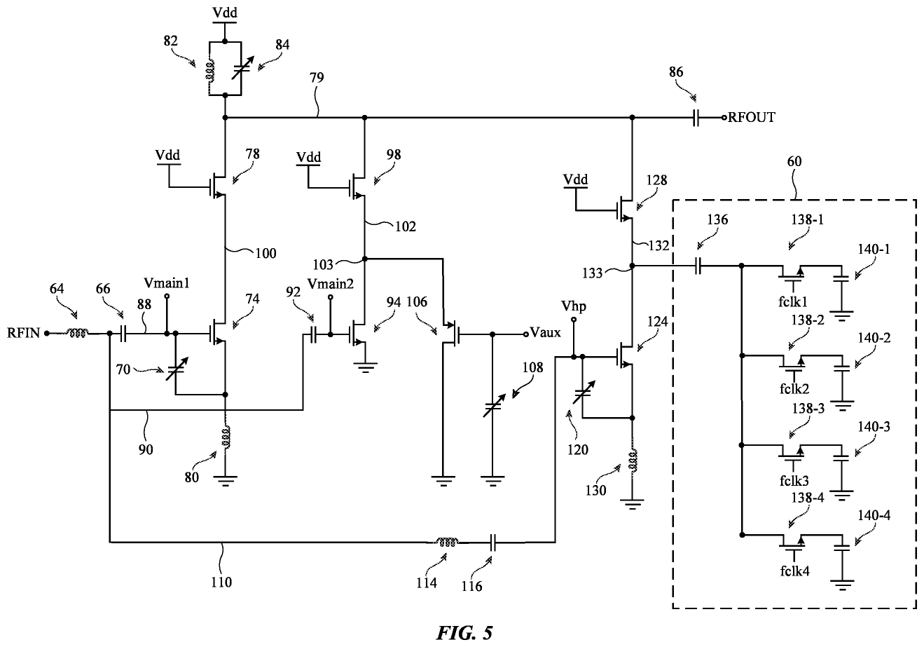

In some illustrative configurations, amplifier 52 of FIG. 4 may include additional components to further improve amplifier performance. In particular, FIG. 5 is a circuit diagram illustrating a configuration of low noise amplifier 52 having an additional (third) amplifying stage (with respect to amplifier 52 in FIG. 4) and a filter coupled to the third amplifying stage for improving amplifier compression point.

As shown in FIG. 5, in addition to the elements described in connection with FIG. 4, amplifier 52 may further include a third amplifying stage formed from amplification transistor 124 coupled in series with cascode transistor 128. In particular, inductor 64, an additional series inductor such as inductor 114, and a series capacitor such as capacitor 116 may couple the input port RFIN to the third amplifying stage. Inductors 64 and 114, capacitor 116, variable capacitor 120, and inductor 130 may form an input matching network for the third amplifying stage.

Amplification transistor 124 (sometimes referred to as core amplification transistor 124 or main amplification transistor 124) may be coupled to input port RFIN via input path 110 (along which inductor 64, inductor 114, and capacitor 116 are coupled). Transistor 124 may be an n-type transistor. N-type transistor 124 may have a drain terminal coupled to path 132, a gate terminal coupled to input RFIN, and a source terminal coupled to inductor 130. Inductor 130 may serve as source degeneration inductor circuitry. Inductor 130 may couple the source terminal of transistor 124 (at a first terminal of inductor 130) to a ground power supply line (at a second terminal of inductor 130).

The gate terminal of transistor 124 may be configured to receive a bias voltage Vhp (e.g., through a bias voltage line coupled to the gate terminal of transistor 124 and supplying the bias voltage). Voltage Vhp may have some intermediate voltage level between the ground voltage level and a positive power supply voltage level Vdd that powers amplifier 52. Voltage Vhp provided to transistor 124 may be the same or different from voltage Vmain1 provided to transistor 74, may be the same or different from voltage Vmain2 provided to transistor 94, and/or may be the same or different from voltage Vaux provided to transistor 106.

The drain terminal of transistor 124 may be coupled to a cascode transistor such as transistor 128. Transistor 128 in combination with amplification transistor 124 may sometimes be referred to as a cascode amplifier, a cascode amplifier circuit, an amplifying cascode stage, or simply an amplifying cascode. Amplification transistor 124 and cascode transistor 128 may collectively form (another) one of the multiple amplifying stages 56 (FIG. 3) in amplifier 52.

Cascode transistor 128 may be an n-type transistor having a gate terminal coupled to a positive power supply line supplying voltage level Vdd, a source terminal coupled to amplification transistor 124, and a drain terminal coupled to the radio-frequency output port RFOUT via output path 79. In particular, the output terminal of this cascode amplifier stage (e.g., at the drain terminal of transistor 128) may produce the output radio-frequency signal corresponding to an amplified version of the input radio-frequency signal received at input RFIN.

Configured in the above-described manner, the first, second, and third amplifying stages may perform amplification operations for an input radio-frequency signal received at input port RFIN in parallel, thereby collectively contributing to the output radio-frequency signal at output port RFOUT. In particular, the first amplifying stage (e.g., transistors 74 and 78) and the third amplifying stage (e.g., transistors 124 and 12) may collectively operate in a high-performance mode of operation. With the inclusion of input matching components and source degeneration to both of these first and third amplifying stages, these two stages may collectively contribute to higher gain for amplifier 52, while exhibiting relatively low noise and power consumption during amplification.

Amplifier 52 may further improve its linearity characteristics by improving the amplifier compression point. To improve the amplifier compression point, amplifier 52 may include a filter circuit such as n-path filter 60 coupled to terminal 133 between amplification transistor 124 and cascode transistor 128.

N-path filter 60 may include a plurality of parallel paths, each including an n-type transistor 138 coupled in series with a capacitor 140 between a ground power supply line and a common capacitor such as capacitor 136. Each of capacitor 140 may have the same capacitance, if desired. Capacitor 136 may couple each of the parallel paths to terminal 133. Each of transistors 138 (e.g., each of the four transistors 138-1, 138-2, 138-3, and 138-4) may receive a control signal based on the same clock signal. The control signals received by transistors 138 may be phase-shifted with respect to one another such that exactly one of all transistors 138 in filter 136 is activated at any given time during operation.

In the example of FIG. 5, n-path filter 160 may include 4 parallel paths and therefore four transistors 138-1, 138-2, 138-3, and 138-4. In one illustrative operating scheme, transistor 138-1 may receive a control signal fclk1 that is asserted during the phases of 1-90 degrees of the clock signal, transistor 138-2 may receive a control signal fclk2 that is asserted during the phases of 91-180 degrees of the clock signal, transistor 138-3 may receive a control signal fclk3 that is asserted during the phases of 181-270 degrees of the clock signal, and transistor 138-4 may receive a control signal fclk4 that is asserted during the phases of 271-360 degrees of the clock signal. A phase generator coupled to transistors 138 may be configured to receive the clock signal and generate each of the control signals for transistors 138.

The use of four parallel paths is illustrative of one of many possible configurations for n-path filter 160. If desired, n-path filter 160 may be implemented using any desired number (n) of parallel paths.

The inclusion of n-path filter 160 may help amplifier 52 improve (e.g., increase) compression point and therefore the linear operating domain of amplifier 52 by reducing undesired voltage swings (e.g., caused by radio-frequency blocker signal components). The coupling of n-path filter 160 to terminal 133 between amplification transistor 124 and cascode transistor 128 may help minimize impact on the noise performance of amplifier 52.

The addition of the third amplifying stage (e.g., transistors 124 and 128 and other coupled components such as inductor 130, capacitor 120, path 110, etc.) and n-path filter 60 into amplifier 52 of FIG. 4, thereby providing amplifier 52 of FIG. 5, is illustrative of one possible configuration. If desired, the addition of these components may be into other types of low noise amplifiers. As an example, the third amplifying stage and n-path filter 60 may be implemented in a low noise amplifier that omits the second amplifying stage (e.g., transistors 94 and 98 and other coupled components such as capacitor 92 and path 90) and the intermodulation distortion suppression circuit (e.g., transistor 106 and capacitor 108).

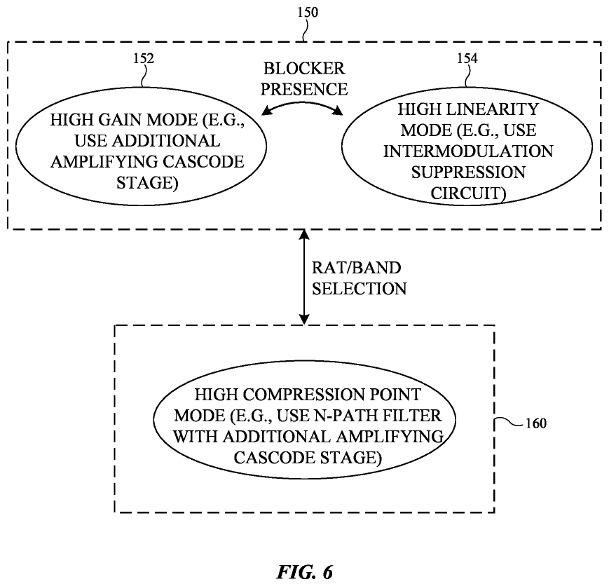

FIG. 6 is a diagram of illustrative modes of operation of a low noise amplifier such as low noise amplifier 52 as described in connection with FIGS. 3-5. In particular, operation of the low noise amplifier may differ depending on different radio access technologies (RATs), operations for different radio-frequency bands, and/or different operating environments.

As shown in FIG. 6, in response to reception of radio-frequency signals conveyed based on a first RAT and/or in first radio-frequency band(s) such as LTE (Long-Term Evolution) protocols and radio-frequency bands, the low noise amplifier may operate in a first set of operating modes 150. In response to reception of radio-frequency signals conveyed based on a second RAT and/or in second radio-frequency band(s) such as GSM (Global System for Mobile communication) protocols and radio-frequency bands, the low noise amplifier may operate in a second set of operating modes 160 or simply mode 160 (in scenarios in which only one operating mode is associated with the second RAT and/or second radio-frequency bands).

In other words, processing circuitry such as processing circuitry 18 and/or one or more processors 26 may determine the RAT and/or radio-frequency bands in use. Responsive to the determined RAT and/or radio-frequency bands, the processing circuitry may provide control signals to one or more components in front end module 40 and/or low noise amplifier 52 to configure low noise amplifier 52 to operate using a mode (e.g., mode 152 or mode 154) in the set of modes 150 or mode 160.

In a first scenario, the low noise amplifier may operate in high gain mode 152 (sometimes referred to herein as high-performance mode 152). In this mode, the low noise amplifier may exhibit a lower current (power) consumption than in mode 154 and/or mode 160, may exhibit a higher gain than in mode 154 and/or mode 160, a lower noise characteristic than in mode 154 and/or mode 160, and may exhibit less linearity (with respect to intermodulation distortion suppression and compression point) than in mode 154 and/or mode 160.

Using amplifier 52 in FIG. 5 as an example, low noise amplifier 52 operating in high gain mode 152 may be configured to activate and use the third amplifying stage (e.g., transistors 124 and 128) in addition to the first amplifying stage (e.g., transistors 74 and 78) to perform the main amplification function of low noise amplifier 52. The second amplifying stage (e.g., transistors 94 and 98) and/or intermodulation distortion suppression circuit 58 (e.g., transistor 106) may or may not be activated and used when low noise amplifier 52 operates in high gain mode 152.

In a second scenario, the low noise amplifier may operate in high linearity mode 154 (sometimes referred to herein as intermodulation suppression mode 154). In this mode, the low noise amplifier may exhibit a higher current (power) consumption than in mode 152 and/or mode 160, may exhibit a higher gain than in mode 152 and/or a lower gain than in mode 160, a higher noise characteristic than in mode 152, and may exhibit higher linearity (with respect to intermodulation distortion suppression) than in mode 152.

Using amplifier 52 in FIG. 5 as an example, low noise amplifier 52 operating in high linear mode 154 may be configured to activate and use the second amplifying stage (e.g., transistors 94 and 98) and intermodulation distortion suppression circuit 58 (e.g., transistor 106) in addition to the first amplifying stage (e.g., transistors 74 and 78) to perform (third-order) intermodulation distortion suppression for low noise amplifier 52 while performing its main amplification functions.

While the low noise amplifier may operate in either mode 152 or mode 154 in response to determining that the low noise amplifier is processing radio-frequency signals associated with a particular RAT and/or radio-frequency band(s), the low noise amplifier may be configured to operate in mode 154 in the presence of one or more radio-frequency blocker signals at (in-band and/or out-of-band) blocker frequencies and configured to operate in mode 152 in the absence of radio-frequency blocker signals.

In other words, processing circuitry such as processing circuitry 18 and/or one or more processors 26 may determine (e.g., after determining the RAT and/or radio-frequency bands in use) an operating environment for wireless circuitry 24 (e.g., for low noise amplifier 52). Responsive to the operating environment containing one or more radio-frequency blocker signals, the processing circuitry may provide control signals to one or more components in front end module 40 and/or low noise amplifier 52 to configure low noise amplifier 52 to operate in mode 154. Responsive to the operating environment lacking (any) radio-frequency blocker signals, the processing circuitry may provide control signals to one or more components in front end module 40 and/or low noise amplifier 52 to configure low noise amplifier 52 to operate in mode 152.

In a third scenario, the low noise amplifier may operate in high compression point mode 160. In this mode, the low noise amplifier may exhibit a higher current (power) consumption than in mode 152 and/or a lower current (power) consumption than in mode 154, may exhibit a lower gain than in mode 152 and/or mode 154, a lower noise characteristic than in mode 152, and may exhibit higher linearity (with respect to compression point) than in mode 152.

Using amplifier 52 in FIG. 5 as an example, low noise amplifier 52 operating in high compression point mode 160 may be configured to activate and use the third amplifying stage (e.g., transistors 124 and 128) and n-path filter 60 (e.g., in addition to the first amplifying stage) to perform the main amplification function of low noise amplifier 52.

The modes of operating a low noise amplifier as described in FIG. 6 are illustrative of some of many possible operating modes for a low noise amplifier such as amplifier 52 in FIGS. 3-5. If desired, amplifier 52 in FIGS. 3-5 may be operated in other manners or modes based on other operating parameters. As examples, depending on the RAT, radio-frequency bands, and/or operating environment, the processing circuitry may adjust the variable capacitances of capacitor 70, capacitor 84, capacitor 108, and capacitor 120 to perform suitable impedance matching, filtering, and/or other functions, may adjust bias voltages Vmain1, Vmain2, Vaux, and Vhp to bias their coupled transistors in different modes of operation, thereby activating or deactivating the different amplifying stages, noise suppression circuits, etc., may adjust the clocking signal frequency for n-path filter 60, and may perform other adjustments for components in amplifier 52.

The methods and operations described above in connection with FIGS. 1-6 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

The foregoing is merely illustrative and various modifications can be made to the described embodiments. The foregoing embodiments may be implemented individually or in any combination.

What is claimed is:

1. Amplifier circuitry comprising:
a first transistor having a gate terminal configured to receive a radio-frequency signal, a drain terminal coupled to an output port of the amplifier circuitry, and a source terminal;
a degeneration inductor coupled to the source terminal of the first transistor;
a second transistor having a gate terminal configured to receive the radio-frequency signal and a drain terminal;
a third transistor having a drain terminal coupled to the output port and a source terminal coupled to the drain terminal of the second transistor; and
a fourth transistor having a source terminal coupled to the drain terminal of the second transistor.

2. The amplifier circuitry of claim 1, wherein the second transistor is a transistor of a first type and the fourth transistor is a transistor of a second type different from the first type.

3. The amplifier circuitry of claim 2, wherein the second transistor is an n-type transistor and the fourth transistor is a p-type transistor.

4. The amplifier circuitry of claim 3, wherein the first transistor is an n-type transistor and the third transistor is an n-type transistor.

5. The amplifier circuitry of claim 1, wherein the second transistor and the third transistor form a first amplifying cascode.

6. The amplifier circuitry of claim 5 further comprising:
a fifth transistor having a drain terminal coupled to the output port and a source terminal coupled to the drain terminal of the first transistor.

7. The amplifier circuitry of claim 6, wherein the first transistor and the fifth transistor form a second amplifying cascode.

8. The amplifier circuitry of claim 1 further comprising:
a first variable capacitor having a first terminal coupled to the gate terminal of the first transistor and a second terminal coupled to the source terminal of the first transistor.

9. The amplifier circuitry of claim 8 further comprising:
a second variable capacitor coupled to the gate terminal of the fourth transistor.

10. The amplifier circuitry of claim 1, wherein the fourth transistor has a gate terminal and the gate terminal of the first transistor, the gate terminal of the second transistor, and the gate terminal of the fourth transistor are each configured to receive a different bias voltage.

11. The amplifier circuitry of claim 1, wherein the first transistor forms a first amplifying stage, the second transistor and the third transistor form a second amplifying stage, and the fourth transistor forms an intermodulation distortion suppression circuit.

12. The amplifier circuitry of claim 1 further comprising:
a fifth transistor having a gate terminal configured to receive the radio-frequency signal, a drain terminal coupled to the output port, and a source terminal; and
an additional degeneration inductor coupled to the source terminal of the fifth transistor.

13. The amplifier circuitry of claim 12 further comprising:
an n-path filter coupled to the drain terminal of the fifth transistor.

14. Amplifier circuitry comprising:
a first transistor having a gate terminal configured to receive a radio-frequency signal, a drain terminal coupled to an output port of the amplifier circuitry, and a source terminal;
a degeneration inductor coupled to the source terminal of the first transistor;
a second transistor having a gate terminal configured to receive the radio-frequency signal and a drain terminal;
a third transistor having a drain terminal coupled to the output port and a source terminal coupled to the drain terminal of the second transistor; and
an n-path filter coupled to the drain terminal of the second transistor.

15. The amplifier circuitry of claim 14, wherein the second transistor has a source terminal, the amplifier circuitry further comprising:
a second degeneration inductor coupled to the source terminal of the second transistor.

16. The amplifier circuitry of claim 15 further comprising:
a fourth transistor having a drain terminal coupled to the output port and a source terminal coupled to the drain terminal of the first transistor.

17. The amplifier circuitry of claim 16, wherein the first transistor and the fourth transistor form a first amplifying cascode stage and the second transistor and the third transistor form a second amplifying cascode stage.

18. The amplifier circuitry of claim 16 further comprising:
a fifth transistor having a gate terminal configured to receive the radio-frequency signal and a drain terminal coupled to the output port; and
an intermodulation distortion suppression circuit coupled to the drain terminal of the fifth transistor.

19. An amplifier comprising:
a first amplifying stage having a first terminal configured to receive a radio-frequency signal and a second terminal coupled to an output port of the amplifier;
a second amplifying stage having a first terminal configured to receive the radio-frequency signal and a second terminal coupled to the output port;
an intermodulation distortion suppression circuit coupled to the second amplifying stage;
a third amplifying stage having a first terminal configured to receive the radio-frequency signal and a second terminal coupled to the output port; and
a filter circuit coupled to the third amplifying stage.

20. The amplifier of claim 19, wherein the second amplifying stage includes a first amplification transistor having a drain terminal, the intermodulation distortion suppression circuit is coupled to the drain terminal of the first amplification transistor, the third amplifying stage includes a second amplification transistor having a drain terminal, the filter circuit comprises an n-path filter, and the n-path filter is coupled to the drain terminal of the second amplification transistor.
